(19) United States
(12) Patent Application Publication
(10) Pub. No.: US 2002/0053710 A1
(43) Pub. Date: May 9, 2002

(54) SEMICONDUCTOR DEVICE HAVING A HIGH BREAKDOWN VOLTAGE

(76) Inventor: Eiji IO, Tokyo (JP)

Correspondence Address: HUTCHINS, WHEELER & DITTMAR, 101 FEDERAL STREET, BOSTON, MA, 02110, US

(21) Appl. No.: 09/550,405

(22) Filed: Apr. 14, 2000

(30) Foreign Application Priority Data
Apr. 16, 1999 (JP) 11-108884

(51) Int. Cl. H01L 31/119; H01L 31/113; H01L 31/062; H01L 29/94

(52) U.S. Cl. 257/408

(57) ABSTRACT

There is provided a semiconductor device including (a) a semiconductor substrate, (b) an insulating film formed at a surface of the semiconductor substrate for defining device regions in each of which a semiconductor device is to be fabricated, (c) a gate electrode formed on the semiconductor substrate, (d) a sidewall covering the gate electrode therewith, and (e) drain and source diffusion layers formed at a surface of the semiconductor substrate around the gate electrode, the sidewall having a sidewall offset extending outwardly of the gate electrode along a surface of the semiconductor substrate in at least one of regions below which the drain and source diffusion layers are to be formed, at least one of the drain and source diffusion layers extending towards the gate electrode beyond an edge of the sidewall offset. The semiconductor device can be fabricated without an increase in the number of fabrication steps and further without generation of a band to band tunneling current, even if CMOS logic transistor and a non-volatile memory are fabricated commonly in the semiconductor device.

### BACKGROUND OF THE INVENTION

1. Field of the Invention

The invention relates to a semiconductor device and a method of fabricating the same, and more particularly to a transistor having a high breakdown voltage which transistor is required in a semiconductor device including both a non-volatile memory and CMOS logic transistor, and a method of fabricating the same.

2. Description of the Related Art

A semiconductor device including both CMOS transistor and a nonvolatile memory is required to have a transistor having a high breakdown voltage, for driving the non-volatile memory.

Such a transistor having a high breakdown voltage has been conventionally fabricated as follows.

FIG. 1 is a cross-sectional view illustrating a first example of a conventional semiconductor device.

The illustrated semiconductor device is comprised of a memory cell 181, NMOS transistor 182 having a high breakdown voltage, PMOS transistor 183 having a high breakdown voltage, Vcc NMOS transistor 184, and Vcc PMOS transistor 185 all formed on a semiconductor substrate 101.

NMOS transistor 182 includes a lightly doped well 103, a thick gate oxide film 152 having a thickness of about 250 angstroms, and thin diffusion layers 168 as source and drain electrodes. Similarly, PMOS transistor 183 includes a lightly doped well 104, a thick gate oxide film 152 having a thickness of about 250 angstroms, and thin diffusion layers 169 as source and drain electrodes. This structure as illustrated provides a high breakdown voltage to NMOS and PMOS transistors 182 and 183.

However, if NMOS and PMOS transistors 182 and 183 are fabricated in a semiconductor device including CMOS transistor and a non-volatile memory, there is caused a problem that the fabrication of NMOS and PMOS transistors 182 and 183 is inconsistent with a process of forming a titanium silicide (TiSi) layer.

First, when heavily doped diffusion layers 165 and 166 of Vcc NMOS and PMOS transistors 184 and 185, and the lightly doped diffusion layers 168 and 169 of NMOS and PMOS transistors 182 and 183 are to be concurrently turned into titanium silicide (TiSi), titanium silicide might abnormally grow on the lightly doped diffusion layers 168 and 169 of NMOS and PMOS transistors 182 and 183. Hence, it would be necessary to prevent the lightly doped diffusion layers 168 and 169 of NMOS and PMOS transistors 182 and 183 from being turned into titanium silicide. To this end, it would be necessary to carry out photolithography steps twice and a film-growth step once for the purpose of protection from ion-implantation of amorphous arsenic and from titanium sputtering.

Second, as illustrated in FIG. 1, if a protection layer 155 composed of HTO, for instance, is formed covering the semiconductor substrate 101 to thereby prevent the lightly doped diffusion layers 168 and 169 of NMOS and PMOS transistors 182 and 183 from being turned into TiSi, there would be caused a problem of formation of a contact.

A diffusion layer which is not to be turned into TiSi is generally necessary to be wet-etched prior to formation of a contact plug. If the diffusion layer is not wet-etched, a resistance of a contact would be increased up to a couple of tens kilo-ohms per a contact. On the other hand, the heavily doped diffusion layers 165 and 166 of Vcc NMOS and PMOS transistors 184 and 185, which are to be turned into TiSi, have to be formed only by dry-etching. This is because if the heavily doped diffusion layers 165 and 166 are wet-etched, a TiSi layer would be much damaged.

Accordingly, the heavily doped diffusion layers 165 and 166 have to be wet-etched by means of photolithography. As a result, once more photolithography step and wet-etching step have to be carried out, resulting in an increase of fabrication steps.

FIG. 2 is a cross-sectional view illustrating a second example of a conventional semiconductor device.

The illustrated semiconductor device is comprised of a memory cell 191, NMOS transistor 192 having a high breakdown voltage, PMOS transistor 193 having a high breakdown voltage, Vcc NMOS transistor 194, and Vcc PMOS transistor 195 all formed on a semiconductor substrate 201.

NMOS transistor 192 includes a lightly doped well 203, a thick gate oxide film 252 having a thickness of about 250 angstroms, and heavily doped diffusion layers 265 as source and drain electrodes. Similarly, PMOS transistor 193 includes a lightly doped well 204, a thick gate oxide film 252 having a thickness of about 250 angstroms, and heavily doped diffusion layers 266 as source and drain electrodes.

The heavily doped diffusion layers 265 and 266 acting as source and drain electrodes in NMOS and PMOS transistors 192 and 193 are formed concurrently with the heavily doped diffusion layers 265 and 266 acting as source and drain electrodes in Vcc NMOS and PMOS transistors 194 and 195. In NMOS and PMOS transistors 192 and 193, a breakdown voltage of the heavily doped diffusion layers 265 and 266 is enhanced only by lightly doping the wells 203 and 204.

The conventional semiconductor device illustrated in FIG. 2 has advantages that the formation of NMOS and PMOS transistors 192 and 193 is consistent with formation of a titanium silicide layer, and that only the small number of fabrication steps are added to a process of fabricating NMOS and PMOS transistors 192 and 193 and Vcc NMOS and PMOS transistors 194 and 195.

However, since the diffusion layers 265 and 266 are heavily doped, there is newly caused a problem that a breakdown voltage between a source and a drain is remarkably lowered due to generation of a band to band tunneling current.

Japanese Unexamined Patent Publication No. 6-188429 has suggested a semiconductor memory device including a semiconductor substrate in which a drain region, a source region, and a channel region sandwiched between the drain and source regions are formed, and memory cells arranged in a matrix. Each of the memory cells is comprised of a tunnel insulating film formed on the semiconductor substrate in the channel region, a floating gate formed on the tunnel insulating film, an interlayer insulating film formed over the floating gate, and a control gate formed on the interlayer insulating film. The drain region in each of the memory cells includes a heavily doped region and a lightly doped region formed around the heavily doped region. The heavily doped region has an end located below the floating gate.

Japanese Unexamined Patent Publication No. 6-244366 has suggested a method of fabricating MOS transistor which method can reduce the number of photolithography steps. In the method, when a first sidewall is formed around a first gate electrode, a semiconductor substrate is exposed in a first region in which a first MOS transistor is to be fabricated. After a second sidewall has been formed around a second gate electrode in a second region in which a second MOS transistor is to be fabricated, source and drain regions are formed in the first and second regions.

Japanese Unexamined Patent Publication No 7-169954 has suggested a method of fabricating a semiconductor device having MIS transistor, comprising the steps of forming MIS transistor having heavily doped drain and source diffusion layers, masking only a gate electrode channel of said MIS transistor, and carrying out ion-implantation to thereby form lightly diffusion layers below the heavily doped source and drain diffusion layers and the gate electrode source and drain diffusion layers.

Japanese Unexamined Patent Publication No. 8-172191 has suggested MOS transistor comprising a semiconductor substrate, a gate insulating film formed on the semiconductor substrate, a gate electrode formed on the gate insulating film, and multi-layered diffusion layers including three layers having first to third impurity concentrations. The third concentration is greater than the second concentration which is greater than the first concentration.

Japanese Unexamined Patent Publication No. 10-116983 has suggested a semiconductor device including a well region formed in a semiconductor substrate having a first electrical conductivity, the well region having a second electrical conductivity, a gate electrode formed on the well region with a gate insulating film being sandwiched therebetween, a heavily doped source diffusion layer having the first electrical conductivity and located adjacent to an end of the gate electrode, a lightly doped drain diffusion layer having the first electrical conductivity and located in facing relation with the source diffusion layer across a channel region, a heavily doped drain diffusion layer having the first electrical conductivity, located remote from the other end of the gate electrode, and contained in the lightly doped drain diffusion layer, and a quite lightly doped diffusion layer having the second electrical conductivity and formed in a region covering the gate electrode and the lightly doped drain diffusion layer.

However, the above-mentioned Publications cannot solve the above-mentioned problem that a breakdown voltage between source and drain regions is remarkably lowered due to generation of a band to band tunneling current.

### SUMMARY OF THE INVENTION

In view of the above-mentioned problem in the above-mentioned conventional semiconductor devices, it is an object of the present invention to provide a semiconductor device including both CMOS logic transistor and a non-volatile memory, which is capable of preventing generation of a band to band tunneling current without an increase in the number of fabrication steps.

It is also an object of the present invention to provide a method of fabricating such a semiconductor device.

In one aspect of the present invention, there is provided a semiconductor device including (a) a semiconductor substrate, (b) an insulating film formed at a surface of the semiconductor substrate for defining device regions in each of which a semiconductor device is to be fabricated, (c) a gate electrode formed on the semiconductor substrate, (d) a sidewall covering the gate electrode therewith, and (e) drain and source diffusion layers formed at a surface of the semiconductor substrate around the gate electrode, the sidewall having a sidewall offset extending outwardly of the gate electrode along a surface of the semiconductor substrate in at least one of regions below which the drain and source diffusion layers are to be formed, at least one of the drain and source diffusion layers extending towards the gate electrode beyond an edge of the sidewall offset.

There is further provided a semiconductor device including (a) a semiconductor substrate, (b) an insulating film formed at a surface of the semiconductor substrate for defining device regions in each of which a semiconductor device is to be fabricated, (c) a gate electrode formed on the semiconductor substrate, (d) a sidewall covering the gate electrode therewith, (e) drain and source diffusion layers formed at a surface of the semiconductor substrate around the gate electrode, and (f) low-resistive wiring layers formed at surfaces of the drain and source diffusion layers, the low-resistive wiring layers being located outwardly beyond a peripheral edge of the sidewall offset, the sidewall having a sidewall offset extending outwardly of the gate electrode along a surface of the semiconductor substrate in at least one of regions below which the drain and source diffusion layers are to be formed, at least one of the drain and source diffusion layers extending towards the gate electrode beyond an edge of the sidewall offset.

It is preferable that the low-resistive wiring layers are composed of TiSi.

It is preferable that the sidewall offset is formed along a surface of the semiconductor substrate in both regions below which the drain and source diffusion layers are to be formed.

It is preferable that the semiconductor device further includes second diffusion layers formed below the drain and source diffusion layers and surrounding the drain and source diffusion layers.

It is preferable that the second diffusion layers have a lower impurity-concentration than that of the drain and source diffusion layers.

It is preferable that the semiconductor device further includes a memory cell formed on the semiconductor substrate.

The present invention can be applied not only to CMOS logic transistor but also to a semiconductor device including both CMOS transistor and a nonvolatile memory.

In another aspect of the present invention, there is provided a method of fabricating a semiconductor device, including the steps of (a) forming an insulating film at a surface of a semiconductor substrate to thereby define device regions in which a semiconductor device is to be formed, b) forming a first well having a first electrical conductivity and a second well having a second electrical conductivity in a first region in which a first transistor is to be fabricated, and further forming a first well having a first electrical conductivity and a second well having a second electrical conductivity in a second region in which a second transistor is to be fabricated, (c) forming a gate electrode of the first transistor in the first region and a gate electrode of the second transistor in the second region, (d) forming first drain and source diffusion layers of the first and second transistors in both the first and second regions, (e) forming a sidewall around the gate electrode of the first transistor, the sidewall having a sidewall offset having an edge remoter from the gate electrode than an edge of the first drain and source diffusion layers on at least one of the first drain and source diffusion layers, and forming a sidewall around the gate electrode of the second transistor, and (f) forming second drain and source diffusion layers of the first transistor in both the first and second regions.

There is further provided a method of fabricating a semiconductor device, including the steps of (a) forming an insulating film at a surface of a semiconductor substrate to thereby define device regions in which a semiconductor device is to be formed, (b) forming a first well having a first electrical conductivity and a second well having a second electrical conductivity in a first region in which a first transistor is to be fabricated, forming a first well having a first electrical conductivity and a second well having a second electrical conductivity in a second region in which a second transistor is to be fabricated, and forming a well in a third region in which a memory cell is to be fabricated, (c) forming a gate electrode of the memory cell in the third region, (d) forming a diffusion layer of the memory cell in the third region, (e) forming a gate electrode of the first transistor in the first region and a gate electrode of the second transistor in the second region, (f) forming first drain and source diffusion layers of the first and second transistors in both the first and second regions, (g) forming a sidewall around the gate electrode of the first transistor, the sidewall having a sidewall offset having an edge remoter from the gate electrode than an edge of the first drain and source diffusion layers on at least one of the first drain and source diffusion layers, and forming a sidewall around the gate electrode of the second transistor, and (h) forming second drain and source diffusion layers of the first transistor in both the first and second regions.

It is preferable that the method further includes the step of lowering a resistance of at least a portion of the second drain and source diffusion layers of the first transistor.

It is preferable that the portion is turned into silicide.

The sidewall offset may be formed in one of the first drain and source diffusion layers, but it is preferable that the sidewall offset is formed in both the first drain and source diffusion layers in the step (g).

The advantages obtained by the aforementioned present invention will be described hereinbelow.

In accordance with the present invention, the heavily doped source and drain diffusion layers are covered with the second diffusion layers comprised of, for instance, lightly doped DDD (double diffused drain) layers, which ensures enhancement in a junction breakdown voltage in a transistor having a high breakdown voltage.

In the present invention, the sidewall is designed to extend for defining a sidewall offset. This structure makes it possible to cause the source and drain diffusion layers of a transistor having a high breakdown voltage, to be spaced away from an edge of a gate electrode. This prevents leakage of a band to band tunneling current, and hence, enhances a breakdown voltage between source and drain diffusion layers.

The sidewall offset comprised of a thick oxide film act as a mask on an edge of a gate electrode. Hence, this mask prevents the second diffusion layers from being exposed at a surface of a semiconductor substrate, and accordingly, it would be possible to prevent the low-resistive wiring layer from abnormally growing above the second diffusion layers.

In addition, since the sidewall offset can be formed only above a drain diffusion layer, for instance, ensuring prevention of unnecessary increase of a chip area.

The present invention can be applied not only to a semiconductor device including both a non-volatile memory and a transistor having a high breakdown voltage, but also solely to a transistor having a high breakdown voltage.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a cross-sectional view of the first example of a conventional semiconductor device.

FIG. 2 is a cross-sectional view of the second example of a conventional semiconductor device.

FIG. 3 is a cross-sectional view of a semiconductor device in accordance with the first embodiment of the present invention.

FIG. 4 is a cross-sectional view of a semiconductor device in accordance with the second embodiment of the present invention.

FIGS. 5A to 5O are cross-sectional views of a semiconductor device, illustrating respective steps of a method of fabricating a semiconductor device in accordance with the first embodiment of the present invention.

FIG. 6 is a cross-sectional view of a semiconductor device, illustrating one step of a method of fabricating a semiconductor device in accordance with the second embodiment of the present invention.

### DESCRIPTION OF THE PREFERRED EMBODIMENTS

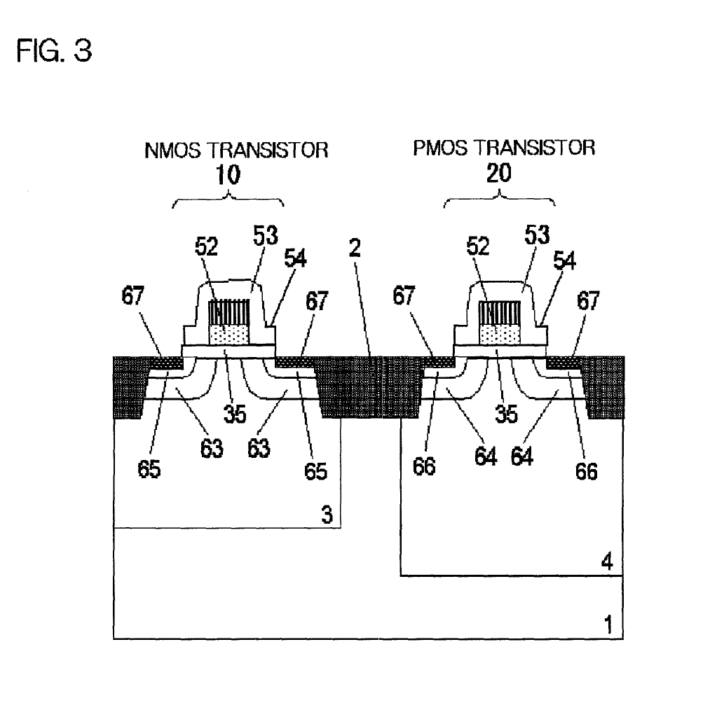

FIG. 3 is a cross-sectional view of a semiconductor device in accordance with the first embodiment.

The semiconductor device in accordance with the first embodiment is fabricated as a transistor having a high breakdown voltage, used in a semiconductor device including both CMOS transistor and a non-volatile memory.

As illustrated in FIG. 3, the semiconductor device is comprised of a semiconductor substrate 1, insulating films 2 formed at a surface of the semiconductor substrate 1 and defining device-formation regions therebetween in which a transistor is to be fabricated, NMOS transistor 10 having a high breakdown voltage, formed in a device-formation region, and PMOS transistor 20 having a high breakdown voltage, formed in a device-formation region.

NMOS transistor 10 is comprised of a p-type well 3 formed in the semiconductor substrate 1 within the device-formation region, a gate oxide film 35 formed on a surface of the pipe well 3, a gate electrode 52 formed on the gate oxide film 35, a sidewall 53 entirely covering the gate electrode 52 therewith, low-resistive wiring layers 67 composed of TiSi and formed at a surface of the p-type well 3, source and drain diffusion layers 65 formed below the TiSi layer 67 to surround the TiSi layer 67 in the p-type well 3, and second diffusion layers or DDD (double diffused drain) layers 63 formed below the source and drain layers 65 to surround the source and drain layers 65.

PMOS transistor 20 is comprised of a n-type well 4 formed in the semiconductor substrate 1 within the device-formation region, a gate oxide film 35 formed on a surface of the n-type well 4, a gate electrode 52 formed on the gate oxide film 35, a sidewall 53 entirely covering the gate electrode 52 therewith, low-resistive wiring layers 67 composed of TiSi and formed at a surface of the n-type well 4, source and drain diffusion layers 66 formed below the TiSi layer 67 to surround the TiSi layer 67 in the n-type well 4, and second diffusion layers or DDD layers 64 formed below the source and drain layers 66 to surround the source and drain layers 66.

In both NMOS and PMOS transistors 10 and 20, DDD layers 63 and 64 are more lightly doped than the source and drain diffusion layers 65 and 66.

As illustrated in FIG. 3, each of the sidewalls 53 in both NMOS and PMOS transistors 10 and 20 is designed to have a sidewall offset 54 extending outwardly of the gate electrode 52 towards the drain and source diffusion layers 65 and 66 along a surface of the gate oxide film 35.

The formation of the sidewall offsets 54 ensure that the drain and source diffusion layers 65 and 66 extend towards the gate electrode 52 beyond peripheral edges of the sidewall offsets 54, and reach the sidewalls 53. That is, distal ends of the drain and source diffusion layers 65 and 66 are located below either the sidewall 53 or the sidewall offset 54.

As a result, the p- and n-type wells 3 and 4 are entirely covered at their surfaces with the TiSi layers 67, and hence, the source and drain diffusion layers 65 and 66 are not exposed at a surface of the semiconductor substrate 1.

In accordance with the first embodiment, it is possible to enhance a junction breakdown voltage by surrounding the heavily doped source and drain diffusion layers 66 and 66 with the lightly doped DDD layers 63 and 64.

In addition, the extension of the sidewalls 63 for defining the sidewall offsets 54 makes it possible to keep the source and drain diffusion layers 65 and 66 of NMOS and PMOS transistors 10 and 20 away from edges of the gate electrodes 52, and hence, to prevent leakage of a band to band tunneling current with the result of enhancement in a breakdown voltage between the source and drain diffusion layers.

In the semiconductor device in accordance with the first embodiment, the sidewall offsets 54 acting as a thick oxide film are kept remained as a mask around the gate electrodes 52 to thereby prevent the lightly doped diffusion layers or DDD layers 63 and 64 from being exposed. Hence, when the TiSi layers 67 are to be formed, the TiSi layers 67 would not abnormally grow on DDD layers 63 and 64.

In addition, since contacts are made only to the source and drain diffusion layers 65 and 66 in which the TiSi layers 67 are formed, there are not paused problems of an increase in contact resistance and addition of steps of forming contacts.

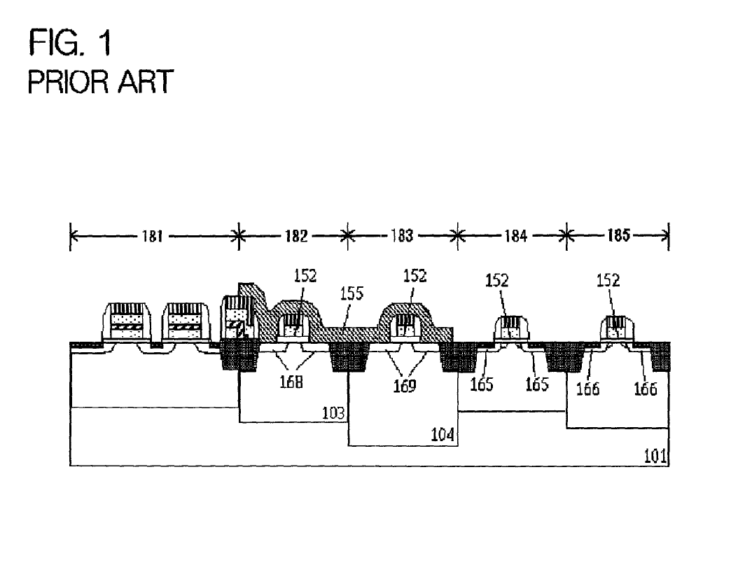

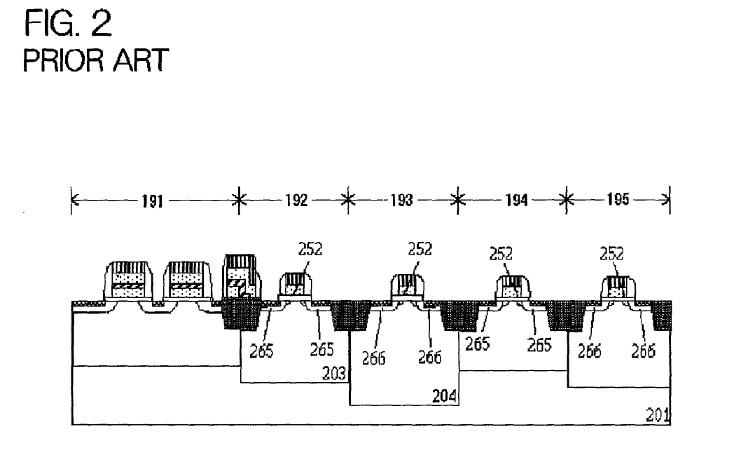

In order to form diffusion layers having different impurity concentrations like the instant embodiment, there have to be carried out photolithography stops twice and a step of forming a mask once, as well as a photolithography step required to form diffusion layers by ion-implantation, in the first example of the conventional semiconductor device illustrated in FIG. 1.

To the contrary, a photolithography step has to be additionally carried out only once in the first embodiment in which the sidewall offsets 54 formed by extending the sidewalls 53 are used as a mask, and steps to be carried out after the formation of the TiSi layers 67 are not necessary to be changed. Hence, a process of fabricating the semiconductor device in accordance with the first embodiment is suitable to fabrication of a semiconductor device including both CMOS logic transistor and a non-volatile memory.

Since p- and n-type wells in NMOS and PMOS transistors are generally lightly doped, they are accompanied with a problem that latch-up is likely to occur. In contrast, in the first embodiment, since the heavily doped source and drain diffusion layers 65 and 66 are surrounded by the lightly doped diffusion layers 63 and 64, it would be possible to prevent production of a parasitic bipolar transistor.

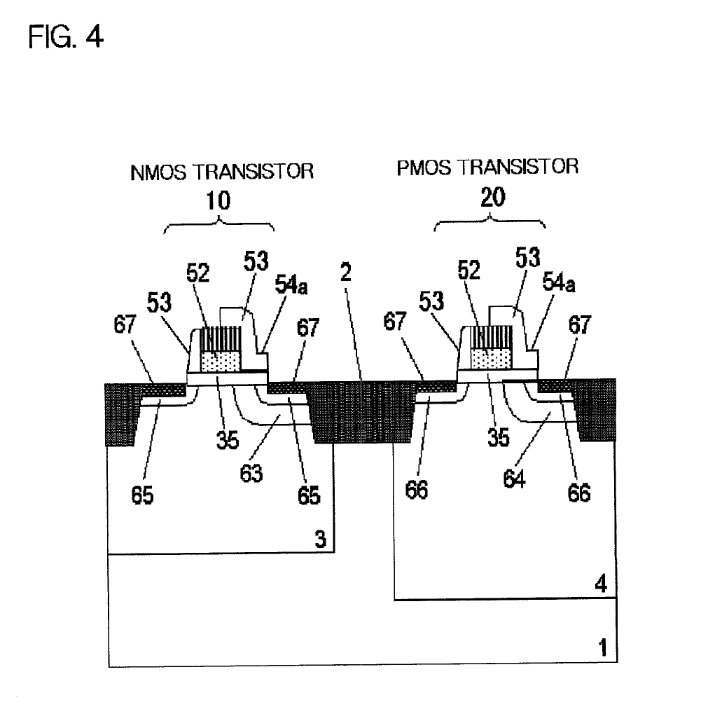

FIG. 4 is a cross-sectional view of a semiconductor device in accordance with the second embodiment.

In the semiconductor device in accordance with the first embodiment, illustrated in FIG. 3, the sidewall offsets 54 are designed to extend towards both the source and drain diffusion layers 65 and 66 from the gate electrode 52. However, it should be noted that the sidewall offset 54a may be designed to extend towards either the source or drain diffusion layers 65 and 66 from the gate electrode 52, as illustrated in FIG. 4.

When the sidewall offset 54a is designed to extend only towards the source diffusion layers 65 and 66, DDD layers 63 and 64 are formed only below the source diffusion layers 65 and 66.

Depending on how NMOS and PMOS transistors 10 and 20 are used, a Vpp voltage is applied only across the gate electrode 52 and the drain diffusion layer 65 or 66, and the Vpp voltage is not applied to the source diffusion layer 65 or 66. Hence, it is not always necessary to design the sidewall offset 54 to extend towards both the source and drain diffusion layers 65 and 66 from the gate electrode 52, and resultingly, the sidewall offset 54a may be designed to extend only toward either the source of drain diffusion layers 65 and 66 from the gate electrode, as illustrated in FIG. 4.

By forming the sidewall offset 54a only in a requisite area, it would be possible to prevent an unnecessary increase in a chip area.

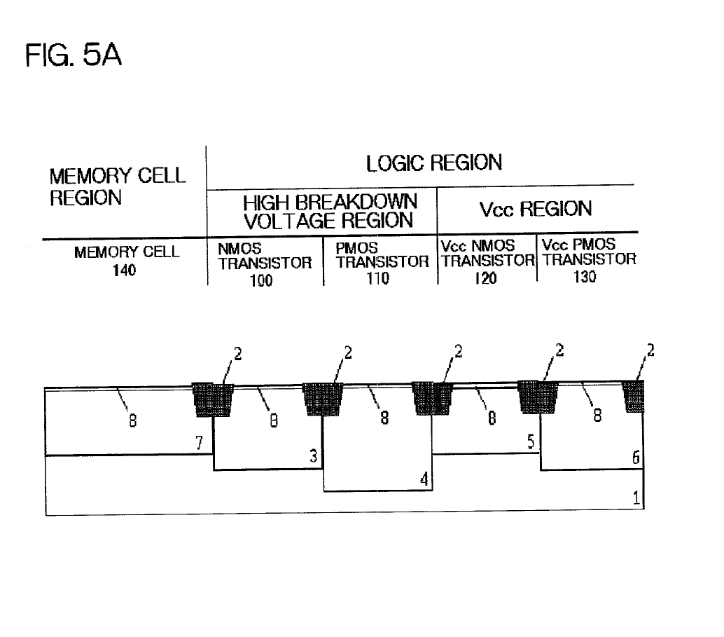

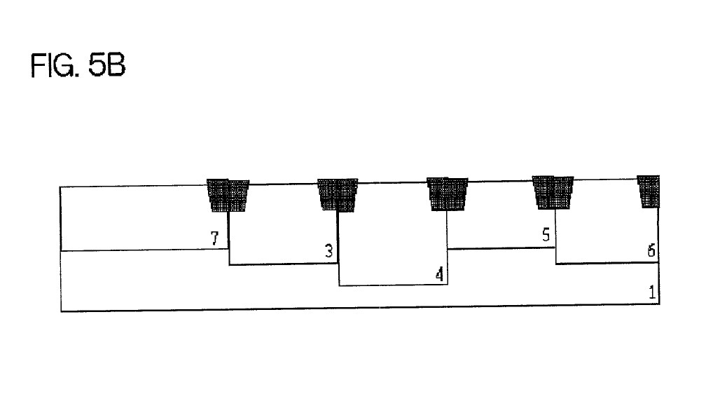

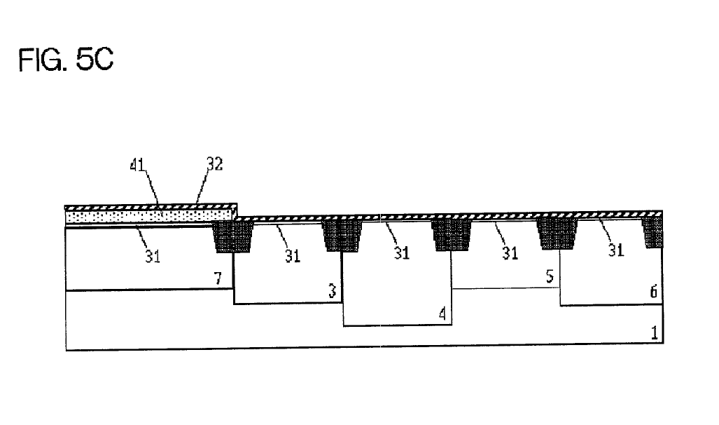

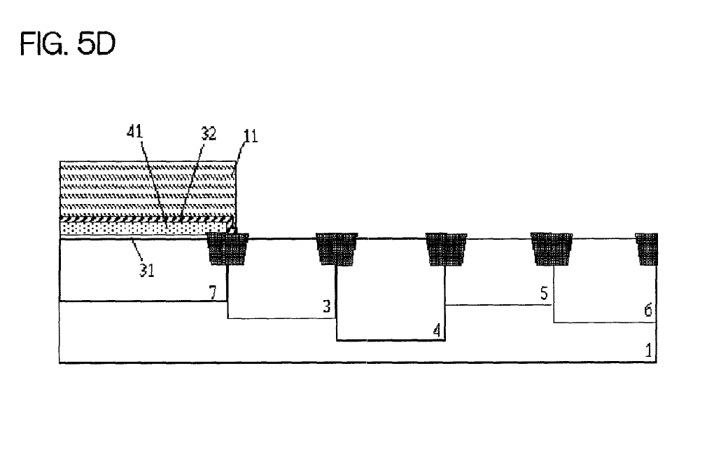

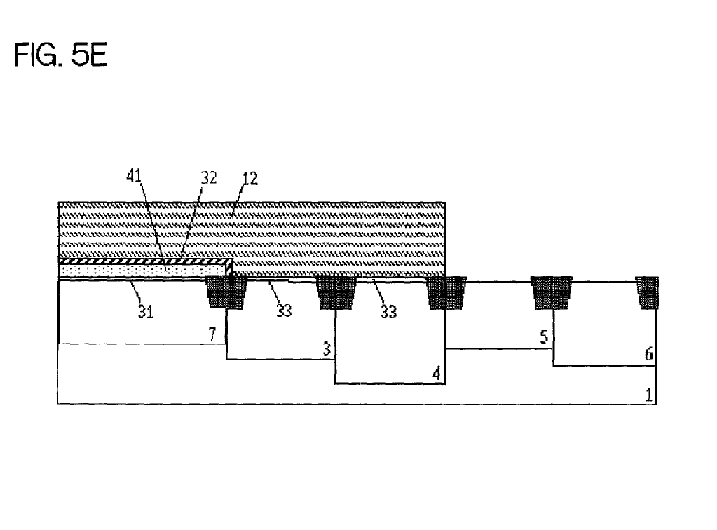

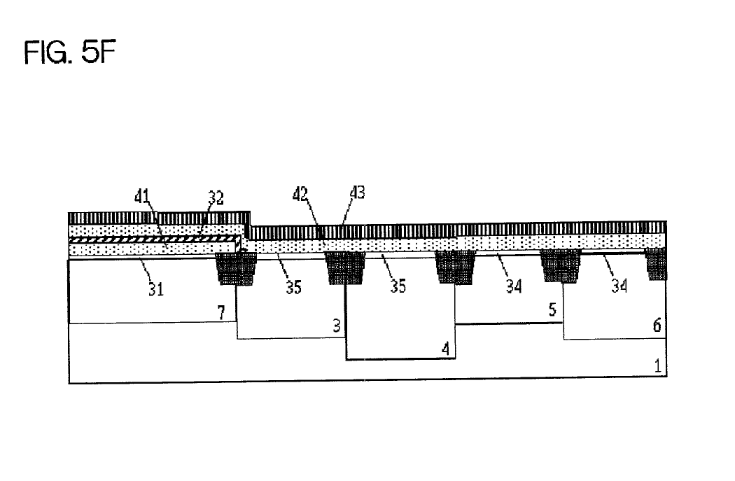

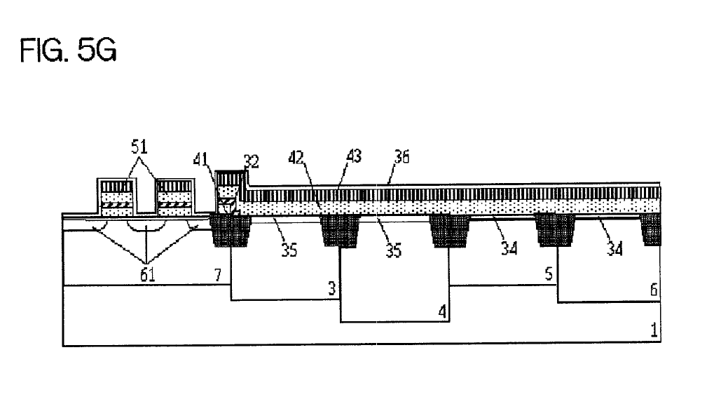

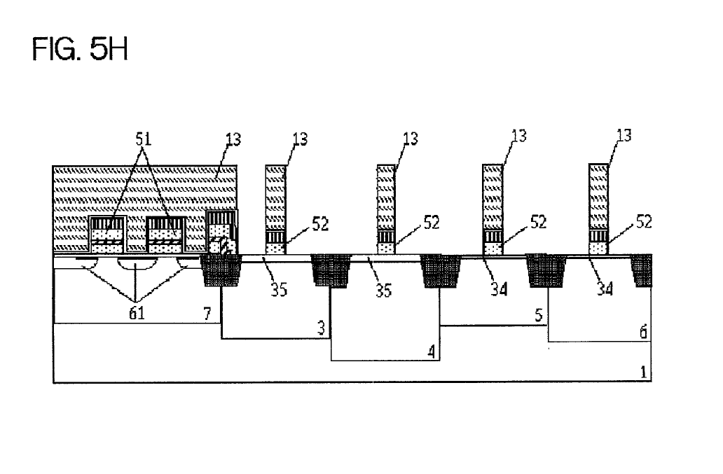

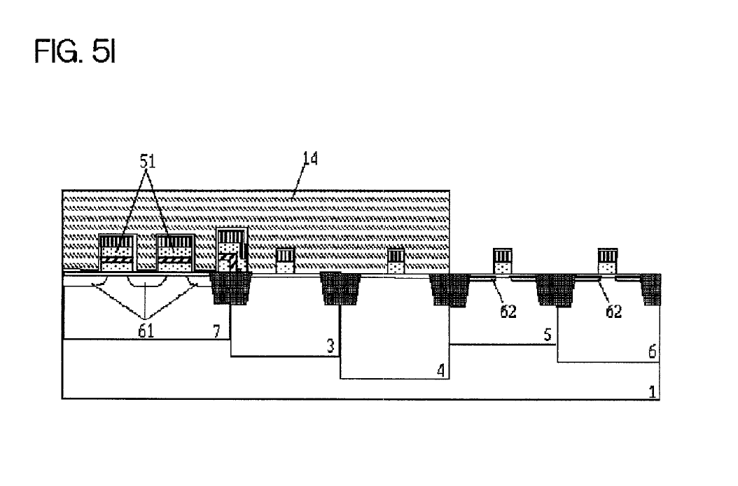

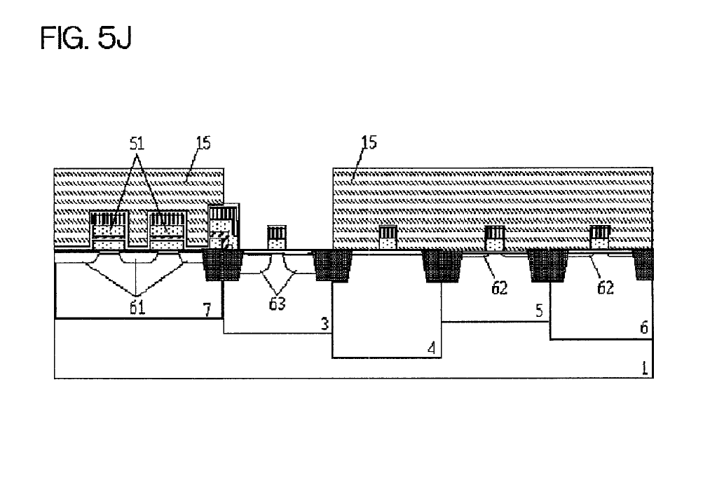

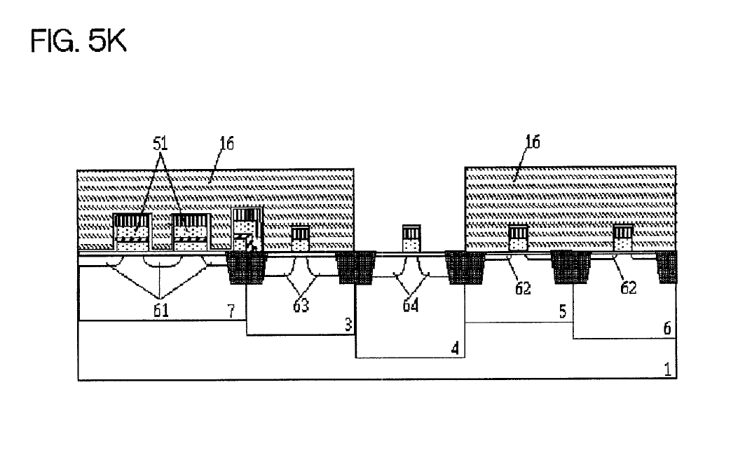

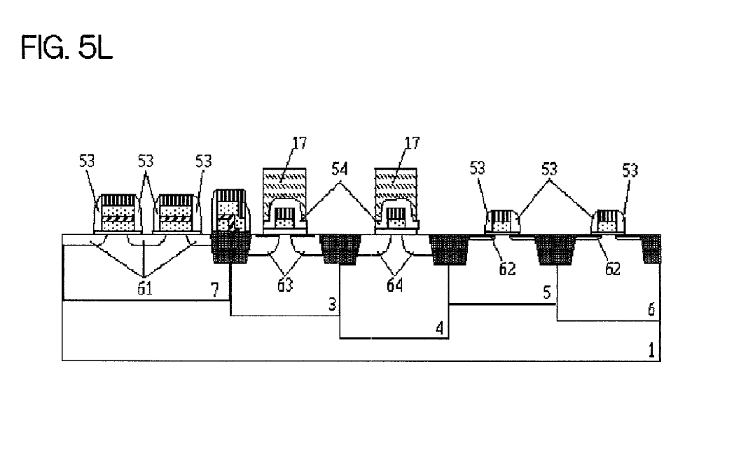

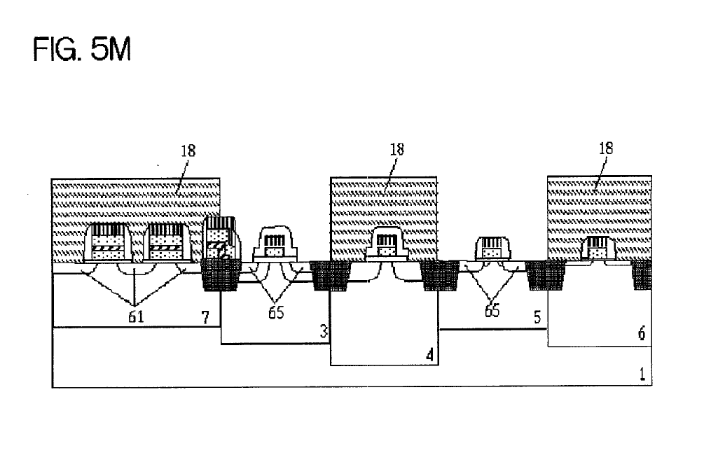

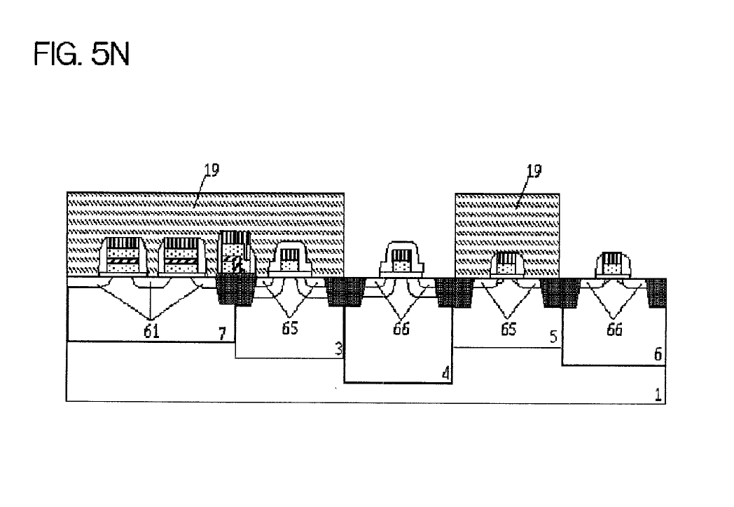

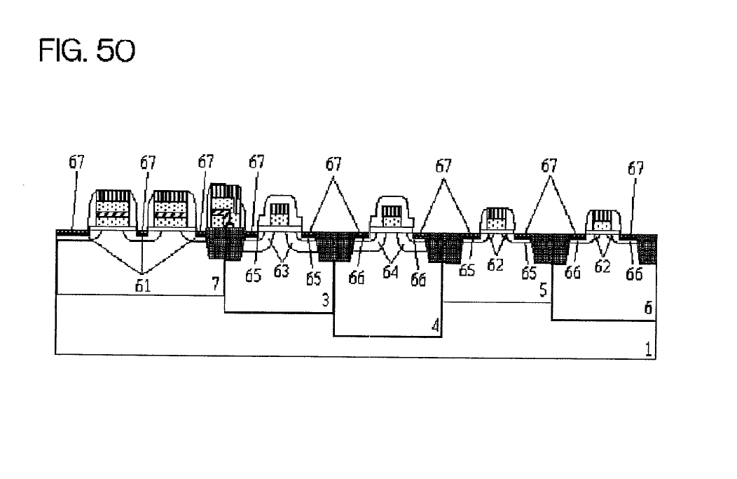

A method of fabricating the semiconductor device in accordance with the first embodiment, illustrated in FIG. 3, is explained hereinbelow with reference to FIGS. 5A to 5O.

In accordance with the method, there are formed NMOS transistor 100 having a high breakdown voltage, PMOS transistor 110 having a high breakdown voltage, Vcc NMOS transistor 120, Vcc PMOS transistor 130 and a memory cell 140 on a semiconductor substrate.

First, as illustrated in FIG. 5A, insulating films 2 are formed at a surface of a semiconductor substrate 1 to define device areas therebetween. A semiconductor device is to be fabricated in each of the thus defined device areas.

Thereafter, there is carried out impurity diffusion or ion-implantation to thereby form p- and n-type wells 3 and 4 in the device areas in which NMOS and PMOS transistors 100 and 110 are to be fabricated, p- and n-type wells 5 and 6 in the device areas in which Vcc NMOS and Vcc PMOS transistors 120 and 130 are to be fabricated, and a well 7 in the device area in which the memory cell 140 is to be fabricated.

When the insulating films 2 are formed, the semiconductor substrate 1 is covered at a surface thereof with a sacrifice oxide film 8.

After the formation of the wells 3-7, the memory cell 140 is fabricated as follows.

As illustrated in FIG. 5B, the sacrifice oxide film 8 is wet-etched for removal.

Then, as illustrated in FIG. 5C, a tunnel oxide film 31 is grown at surfaces of the wells 3-7 by thermal oxidation. Then, a first polysilicon layer 41 which will make a floating gate is formed on the tunnel oxide film 31. Since the first polysilicon layer 41 is unnecessary to be formed in areas other than an area in which the memory cell 140 is to be fabricated, the first polysilicon layer 41 is removed by photolithography and plasma-etching in area in which the transistors 100, 110, 120 and 140 are to be fabricated.

Then, an insulating film or ONO film 32 is formed entirely over the first polysilicon layer 41 and the semiconductor substrate 1.

Then, a gate oxide film is formed in area in which the transistors 100, 110, 120 and 130 are to be fabricated, as follows.

As illustrated in FIG. 5D, a photoresist film 11 is formed and patterned in such a manner that the photoresist film 11 exists only above an area in which the memory cell 140 is to be fabricated. Then, the insulating film 32 and the tunnel oxide film 31 are plasma-etched for removal in areas in which the transistors 100, 110, 120 and 130 are to be fabricated, with the patterned photoresist film 11 being used as a mask.

Then, the photoresist film 11 is removed.

Then, an oxide film 33 is formed by thermal oxidation in areas in which the transistors 100, 110, 120 and 130 are to be fabricated.

Then, as illustrated in FIG. 5E, a photoresist film 12 is formed and patterned such that the photoresist film 12 exists only on areas in which NMOS and PMOS transistors 100 and 110 and the memory cell 140 are to be fabricated. Then, the oxide film 33 is wet-etched for removal in areas in which Vcc NMOS and PMOS transistors 120 and 130 are to be fabricated, with the photoresist film 12 being used as a mask.

After removal of the photoresist film 12, a gate oxide film 34 is formed by thermal oxidation in areas in which Vcc NMOS and PMOS transistors 120 and 130 are to be fabricated. While the gate oxide film 34 is being formed, the oxide film 33 is exposed to oxidation environment, and thus, turned into a gate oxide film 35 in areas in which NMOS and PMOS transistors 100 and 110 are to be fabricated.

After the formation of the gate oxide films 34 and 35, a second polysilicon layer 42 and a tungsten silicide (WSi) layer 43 are successively formed over the semiconductor substrate 1, as illustrated in FIG. 5F.

Then, the memory cell 140 is fabricated as follows.

First, as illustrated in FIG. 5G, gate electrodes 51 of the memory cell 140 are fabricated by photolithography and plasma-etching. Then, a through film or HTO film 36 is formed entirely over the product resulted from the steps having been carried out so far, followed by ion-implantation, to thereby diffusion layers 61 of the memory cell 140. The diffusion layers 61 of the memory cell 140 are designed to have the same impurity concentration as those of the diffusion layers of the Vcc NMOS and PMOS transistors 120 and 130.

After the fabrication of the memory cell 140, as illustrated in FIG. 5H, a photoresist film 13 is deposited all over the product illustrated in FIG. 5G, and then, is patterned. By using the thus patterned photoresist film 13 as a mask, the through film 36, the tungsten silicide layer 43 and the second polysilicon layer 42 are plasma-etched to thereby form gate electrodes 52 of NMOS and PMOS transistors 100 and 110 and Vcc NMOS and PMOS transistors 120 and 130, as illustrated in FIG. 5H.

After removal of the photoresist film 13, a photoresist film 14 is formed and patterned so that the photoresist film 14 exists only in areas in which the memory cell 140 and NMOS and PMOS transistors 100 and 110 are to be fabricated, as illustrated in FIG. 5I. Then, the semiconductor substrate 1 is ion-implanted with phosphorus and boron in areas in which Vcc NMOS and PMOS transistors 120 and 130 are to be fabricated, to thereby form LDD layers 62 in the wells 5 and 6.

After removal of the photorosist film 14, a photoresist film 15 is formed and patterned so that the photoresist film 15 exists only in areas in which the memory cell 140, PMOS transistor 110, and Vcc NMOS and PMOS transistors 120 and 130 are to be fabricated, as illustrated in FIG. 5J. Then, the semiconductor substrate 1 is ion-implanted with phosphorus in an area in which NMOS transistor 100 is to be fabricated, to thereby form DDD layers 63 in the well 3.

After removal of the photoresist film 15, a photoresist film 16 is formed and patterned so that the photoresist film 16 exits only in areas in which the memory cell 140, NMOS transistor 100, and Vcc NMOS and PMOS transistors 120 and 130 are to be fabricated, as illustrated in FIG. 5K. Then, the semiconductor substrate 1 is ion-implanted with boron in an area in which PMOS transistor 110 is to be fabricated, to thereby form DDD layers 64 in the well 4.

After removal of the photoresist film 16, a sidewall HTO layer is formed covering the gate electrodes 51 and 52 therewith. Then the sidewall HTO layer is plasma-etched to thereby define sidewalls 53 around the gate electrodes 51 and 52.

When the sidewalls 53 are formed, a patterned photoresist film 17 is formed on the sidewall HTO layer covering the gate electrodes 52 of NMOS and PMOS transistors 100 and 110, as illustrated in FIG. 5L. The sidewalls 53 around the gate electrodes 52 of NMOS and PMOS transistors 100 and 110 are formed to have extensions with the patterned photoresist film 17 being used as a mask.

Thus, sidewall offsets 54 are formed around the gate electrodes 52 of NMOS and PMOS transistors 100 and 110.

After the formation of the sidewalls 53 and the sidewall offsets 54, the heavily doped diffusion layers 65 and 66 of Vcc NMOS and PMOS transistors 120 and 130 are formed in the wells 5 and 6, as follows As illustrated in FIG. 5M, a photoresist film 18 is formed and patterned so that the photoresist film 18 exists only in areas in which the memory call 140, PMOS transistor 110, and Vcc PMOS transistor 130 are to be fabricated. Then, the semiconductor substrate 1 is ion-implanted with impurity in areas in which NMOS transistor 100 and Vcc NMOS transistor 120 are to be fabricated, to thereby form the n-channel diffusion layers 65 in the wells 3 and 5.

After removal of the photoresist film 18, a photoresist film 19 is formed and patterned so that the photoresist film 19 exists only in areas in which the memory cell 140, NMOS transistor 100, and Vcc NMOS transistor 120 are to be fabricated. Then, the semiconductor substrate 1 is ion-implanted with impurity in areas in which PMOS transistor 110 and Vcc PMOS transistor 130 are to be fabricated, to thereby form the p-channel diffusion layers 66 in the wells 4 and 6.

The sidewall offsets 54 formed by horizontally extending the sidewalls 53 do not allow the source and drain diffusion layers 65 and 66 to overlap the gate electrodes of the NMOS and PMOS transistors 100 and 110, and as a result, it is possible to avoid generation of a band to band tunneling current while the n- and p-channel diffusion layers 65 and 66.

Then, as illustrated in FIG. 50, the source and drain diffusion layers 65 and 66 are partially turned into titanium silicide (TiSi).

Since the sidewall offsets 54 disallow the lightly doped diffusion layers 63 and 64 to be exposed outside, it is possible to partially turn the source and drain diffusion layers 65 and 66 into titanium silicide without modification of a process of fabricating Vcc NMOS and PMOS transistors 120 and 130.

The TiSi layer 67 is formed as follows.

After removal of the photoresist film 19, arsenic is implanted entirely into the semiconductor substrate 1 to thereby render the semiconductor substrate 1 amorphous at a surface thereof in order to facilitate silicidation of the source and drain diffusion layers 65 and 66. Then, an oxide film (not illustrated) formed on the source and drain diffusion layers 65 and 66 are removed by plasma-etching and wet-etching. Then, titanium sputtering is carried out onto the semiconductor substrate 1.

Then, the resultant is thermally annealed, and extra titanium is wet-etched for removal. Thus, the titanium silicide layers 67 are formed at surfaces of the source and drain diffusion layers 65 and 66.

Thereafter, an interlayer insulating film (not illustrated) is formed, and then, a contact is made through upper and lower wiring layers. Namely, a process of forming a multi-layered wiring structure is carried out.

Thus, there is completed the semiconductor device including the memory cell 140, NMOS and PMOS transistors 100 and 110, and Vcc NMOS and PMOS transistors 120 and 130.

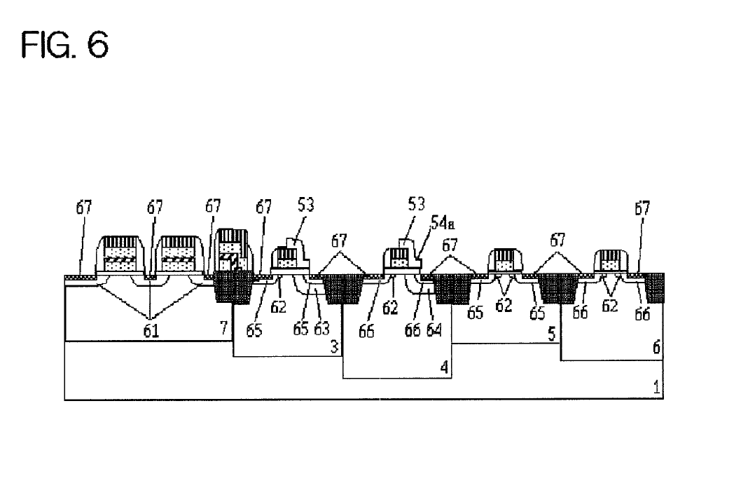

FIG. 6 illustrates a method of fabricating the semiconductor device in accordance with the second embodiment, illustrated in FIG. 4.

The method of fabricating the semiconductor device in accordance with the second embodiment is different from the method of fabricating the semiconductor device in accordance with the first embodiment in that sidewall offsets 54a are formed only above the drain diffusion layers 65 and 66.

The sidewall offsets 54a can be formed merely by changing a pattern of the photoresist film 17 in the step illustrated in FIG. 5L. That is, though the photoresist, film 17 illustrated in FIG. 5L entirely covers the gate electrodes 52 therewith, the photoresist film 17 in the second embodiment is designed to cover only half of the gate electrodes 52.

When the sidewall offsets 54a are formed only above the drain diffusion layers 65 and 66, DDD layers 63 and 64 are formed only below the drain diffusion layers 65 and 66.

Depending on how NMOS and PMOS transistors 100 and 110 are used, a Vpp voltage is applied only across the gate electrode 52 and the drain diffusion layer 65 or 66, and the Vpp voltage is not applied to the source diffusion layer 65 or 66. Hence, it is not always necessary to design the sidewall offsets 54 to extend towards both the source and drain diffusion layers 65 and 66 from the gate electrode 52, and resultingly, the sidewall offset 54a may be designed to extend only toward either the source of drain diffusion layers 65 and 66 from the gate electrode.

By forming the sidewall offset 54a only in a requisite area, it would be possible to prevent an unnecessary increase in a chip area.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 11-108884 filed on Apr. 16, 1999 including specification, claims, drawings and summary is incorporated herein by reference in its entirety.

What is claimed is:

1. A semiconductor device comprising:
(a) a semiconductor substrate;
(b) an insulating film formed at a surface of said semiconductor substrate for defining device regions in each of which a semiconductor device is to be fabricated;
(c) a gate electrode formed on said semiconductor substrate;
(d) a sidewall covering said gate electrode therewith; and
(e) drain and source diffusion layers formed at a surface of said semiconductor substrate around said gate electrode,
said sidewall having a sidewall offset extending outwardly of said gate electrode along a surface of said semiconductor substrate in at least one of regions below which said drain and source diffusion layers are to be formed,
at least one of said drain and source diffusion layers extending towards said gate electrode beyond an edge of said sidewall offset.

2. The semiconductor device as set forth in claim 1, wherein said sidewall offset is formed along a surface of said semiconductor substrate in both regions below which said drain and source diffusion layers are to be formed.

3. The semiconductor device as set forth in claim 1, further comprising second diffusion layers formed below said drain and source diffusion layers and surrounding said drain and source diffusion layers.

4. The semiconductor device as set forth in claim 3, wherein said second diffusion layers have a lower impurity-concentration than that of said drain and source diffusion layers.

5. The semiconductor device as sot forth in claim 1, further comprising a memory cell formed on said semiconductor substrate.

6. A semiconductor device comprising:
(a) a semiconductor substrate;
(b) an insulating film formed at a surface of said semiconductor substrate for defining device regions in each of which a semiconductor device is to be fabricated;
(c) a gate electrode formed on said semiconductor substrate;
(d) a sidewall covering said gate electrode therewith;
(e) drain and source diffusion layers formed at a surface of said semiconductor substrate around said gate electrode; and
(f) low-resistive wiring layers formed at surfaces of said drain and source diffusion layers, said low-resistive wiring layers being located outwardly beyond a peripheral edge of said sidewall offset,
said sidewall having a sidewall offset extending outwardly of said gate electrode along a surface of said semiconductor substrate in at least one of regions below which said drain and source diffusion layers are to be formed,
at least one of said drain and source diffusion layers extending towards said gate electrode beyond an edge of said sidewall offset.

7. The semiconductor device as set forth in claim 6, wherein said low-resistive wiring layers are composed of TiSi.

8. The semiconductor device as set forth in claim 6, wherein said sidewall offset is formed along a surface of said semiconductor substrate in both regions below which said drain and source diffusion layers are to be formed.

9. The semiconductor device as sot forth in claim 6, further comprising second diffusion layers formed below said drain and source diffusion layers and surrounding said drain and source diffusion layers.

10. The semiconductor device as set forth in claim 9, wherein said second diffusion layers have a lower impurity-concentration than that of said drain and source diffusion layers.

11. The semiconductor device as set forth claim 6, further comprising a memory cell formed on said semiconductor substrate.

12. A method of fabricating a semiconductor device, comprising the steps of:
(a) forming an insulating film at a surface of a semiconductor substrate to thereby define device regions in which a semiconductor device is to be formed;
(b) forming a first well having a fast electrical conductivity and a second well having a second electrical conductivity in a first region in which a first transistor is to be fabricated, and further forming a first well having a first electrical conductivity and a second well having a second electrical conductivity in a second region in which a second transistor is to be fabricated;
(c) forming a gate electrode of said first transistor in said first region and a gate electrode of said second transistor in said second region;
(d) forming first drain and source diffusion layers of said first and second transistors in both said first and second regions;
(e) forming a sidewall around said gate electrode of said first transistor, said sidewall having a sidewall offset having an edge remoter from said gate electrode than an edge of said first drain and source diffusion layers on at least one of said first drain and source diffusion layers, and forming a sidewall around said gate electrode of said second transistor; and
(f) forming second drain and source diffusion layers of said first transistor in both said first and second regions.

13. The method as set forth in claim 12, further comprising the step of lowering a resistance of at least a portion of said second drain and source diffusion layers of said first transistor.

14. The method as set forth in claim 13, wherein said portion is turned into silicide.

15. The method as set forth in claim 12, wherein said sidewall offset is formed in both said first drain and source diffusion layers in said step (e).

16. A method of fabricating a semiconductor device, comprising the steps of:
(a) forming an insulating film at a surface of a semiconductor substrate to thereby define device regions in which a semiconductor device is to be formed;
(b) forming a first well having a first electrical conductivity and a second well having a second electrical conductivity in a first region in which a first transistor is to be fabricated, forming a first well having a first electrical conductivity and a second well having a second electrical conductivity in a second region in which a second transistor is to be fabricated, and forming a well in a third region in which a memory cell is to be fabricated;
(c) forming a gate electrode of said memory cell in said third region;
(d) forming a diffusion layer of said memory cell in said third region;
(e) forming a gate electrode of said first transistor in said first region and a gate electrode of said second transistor in said second region;
(f) forming first drain and source diffusion layers of said first and second transistors in both said first and second regions;
(g) forming a sidewall around said gate electrode of said first transistor, said sidewall having a sidewall offset having an edge remoter from said gate electrode than an edge of said first drain and source diffusion layers on at least one of said first drain and source diffusion layers, and forming a sidewall around said gate electrode of said second transistor; and
(h) forming second drain and source diffusion layers of said first transistor in both said first and second regions.

17. The method as set forth in claim 16, further comprising the step of lowering a resistance of at least a portion of said second drain and source diffusion layers of said first transistor.

18. The method as set forth in claim 17, wherein said portion is turned into silicide.

19. The method as set forth in claim 16, wherein said sidewall offset is formed in both said first drain and source diffusion layers in said step (g).
